(19) United States
(12) Patent Application Publication
(10) Pub. No.: US 2018/0231618 A1
(43) Pub. Date: Aug. 16, 2018

(54) MAGNETIC SENSOR APPARATUS

(71) Applicant: TDK Corporation, Tokyo (JP)

(72) Inventors: Naoki OHTA, Tokyo (JP); Shunji SARUKI, Tokyo (JP)

(21) Appl. No.: 15/791,555

(22) Filed: Oct. 24, 2017

(30) Foreign Application Priority Data
Feb. 16, 2017 (JP) 2017-26943

(51) Int. Cl. G01R 33/00

(52) U.S. Cl. CPC G01R 33/0035

(57) ABSTRACT

A magnetic sensor apparatus includes: a first magnetic detection element unit, which outputs a first sensor signal, and a second magnetic detection element unit, which outputs a second sensor signal, based on change in an external magnetic field; a first operation processing unit, which calculates a predetermined physical quantity based on the first sensor signal; a second operation processing unit, which calculates a predetermined physical quantity based on the second sensor signal; and a sealing unit, which seals at least the first magnetic detection element unit and the second magnetic detection element unit as a single body.

### CROSS REFERENCE TO RELATED APPLICATIONS

The present application is based on Japanese Patent Application No. 2017-26943 filed on Feb. 16, 2017, the disclosure of which is incorporated herein by reference.

### FIELD OF THE INVENTION

The present invention relates to a magnetic sensor apparatus.

### BACKGROUND OF THE INVENTION

In recent years, physical quantity detection apparatuses have been used for detecting physical quantities of moving bodies such as the position, amount of movement (amount of change), movement speed or the like through rotational movement or linear movement, in a variety of applications. As one such physical quantity detection apparatus is provided with a magnetic sensor apparatus capable of detecting change in an external magnetic field accompanying movement of a moving body, and a signal indicating the relative positional relationship between the moving body and the magnetic sensor apparatus is output from the magnetic sensor apparatus.

The magnetic sensor apparatus included in the physical quantity detection apparatus includes a magnetic detection element for detecting a detection magnetic field. The magnetic detection element is a magnetoresistive effect element (MR element), which is a laminated body having a free layer and a magnetization pinned layer. In the MR element, resistance changes accompany changes in the magnetization direction of the free layer in accordance with an external magnetic field. Such elements are known as a Hall elements that use the so-called Hall effect and are known as magnetic detection elements.

The physical quantity detection apparatus is used for example as a torque sensor or the like that detects steering torque in an electric power steering apparatus that assists a driver's steering force through the power of an electric motor. The magnetic sensor apparatus included in the physical quantity detection apparatus applied to this kind of torque sensor has a plurality of magnetic sensor units and a sealing unit that resin-seals the plurality of magnetic sensor units as a single body. The magnetic sensor units include a magnetic detection element and an operation processing unit that calculates the physical quantity from signals output by the magnetic detection elements. With this kind of magnetic sensor apparatus, even when one of the plurality of magnetic sensor units outputs an abnormal signal because of a malfunction or the like, it is possible to detect the malfunction or the like through comparison with the signals output from the other magnetic sensor units.

### PRIOR ART

### Patent Literature

### [Patent Literature 1]

### JP Laid-Open Patent Application No. 2015-116964

### SUMMARY OF THE INVENTION

### Problem to be Solved by the Invention

The magnetic sensor units included in the above-described magnetic sensor apparatus have the same structure. For example, TMR elements having the same film structure are used as the magnetic detection elements included in the magnetic sensor units, and the physical quantity is calculated from signals output by the TMR elements through a program that calculates the physical quantity by means of the same algorithm, in the operation processing units. When the physical quantity is calculated by the same algorithm in each of the operation processing units, there are cases in which erroneous physical quantities are calculated due to predetermined common factors in each of the plurality of magnetic sensor units. In such cases, situations arise in which the physical quantities calculated by each of the operation processing units substantially coincide but differ from the actual physical quantity, creating the fear that the reliability of the magnetic sensor apparatus will decline.

In consideration of the foregoing, it is an objective of the present invention to provide a highly reliable magnetic sensor apparatus that includes a plurality of magnetic detection element units and plurality of operation processing units and that, even when abnormal situations arise in which erroneous physical quantities are calculated in the operation processing units, such abnormalities are quickly recognized.

### Means for Solving the Problem

In order to solve the above-described problem, the present invention provides a magnetic sensor apparatus comprising: a first magnetic detection element unit that outputs a first sensor signal based on change in an external magnetic field; a second magnetic detection element unit that outputs a second sensor signal based on change in the external magnetic field; a first operation processing unit that calculates a predetermined physical quantity based on the first sensor signal; a second operation processing unit that calculates a predetermined physical quantity based on the second sensor signal; and a sealing unit that seals at least the first magnetic detection element unit and the second magnetic detection element unit as a single body; wherein the first operation processing unit calculates the physical quantity based on a first operation algorithm, and the second operation processing unit calculates the physical quantity, which is of the same type as the physical quantity calculated by the first operation processing unit, based on a second operation algorithm of a different type from the first operation algorithm (Invention 1).

In the above-described invention (Invention 1), the first operation processing unit, which calculates the physical quantity based on the first sensor signal output from the first magnetic detection element unit, and the second operation processing unit, which calculates the physical quantity based on the second sensor signal output from the second magnetic detection element unit, calculate the physical quantity through mutually differing types of operation algorithms. Through this, when an erroneous physical quantity is calculated by one of the operation algorithms, the calculation results of the physical quantity from the first operation processing unit and the second operation processing unit do not match, so it is possible to swiftly comprehend the abnormality in the magnetic sensor apparatus.

In the present invention, “different types of the operation algorithms” means that algorithms for calculating the physical quantity differ such that an abnormal physical quantity is not calculated through common factors. In addition, in the present invention rotation angle, rotation amount, rotation speed, moving amount, moving speed and the like, for example, are examples of “types of physical quantities”.

In the above-described invention (Invention 1), preferably the first magnetic detection element unit and the second magnetic element unit both include magnetoresistive effect elements (Invention 2), the magnetoresistive effect elements included in the first magnetic detection element unit and the magnetoresistive effect elements included in the second magnetic detection element unit preferably are mutually the same type of magnetoresistive effect elements (Invention 3), and the magnetoresistive effect elements included in the first magnetic detection element unit and the magnetoresistive effect elements included in the second magnetic detection element unit are preferably magnetoresistive effect elements with behaviors that are different from each other in resistance value changes based on changes in the external magnetic field (Invention 4).

The above-described invention (Invention 1) may further include a first magnetic sensor unit, which includes the first magnetic detection element unit and the first operation processing unit, and a second magnetic sensor unit, which includes the second magnetic detection element unit and the second operation processing unit, and the sealing unit seals the first magnetic sensor unit and the second magnetic sensor unit as a single body (Invention 5), and the above-described invention (Invention 1) may further include an operation processing unit that includes the first operation processing unit and the second operation processing unit, and the sealing unit seals the first magnetic detection element unit, the second magnetic detection element unit and the operation processing unit as a single body (Invention 6).

In addition, the above-described invention (Invention 1) may further include a third magnetic detection element unit, which outputs a third sensor signal based on change in the external magnetic field, and a third operation processing unit, which calculates a predetermined physical quantity based on the third sensor signal. The sealing unit seals at least the first magnetic detection element unit, the second magnetic detection element unit and the third magnetic detection element unit as a single body. The third operation processing unit calculates the physical quantity, which is of the same type as the physical quantities respectively calculated by the first operation processing unit and the second operation processing unit, based on a third operation algorithm of a type differing from both the first operation algorithm and the second operation algorithm (Invention 7).

The above-described invention (Invention 7) may further include a first magnetic sensor unit, which includes the first magnetic detection element unit and the first operation processing unit, a second magnetic sensor unit, which includes the second magnetic detection element unit and the second operation processing unit, and a third magnetic sensor unit, which includes the third magnetic detection element unit and the third operation processing unit, and the sealing unit seals the first magnetic sensor unit, the second magnetic sensor unit and the third magnetic sensor unit as a single body (Invention 8), and the above-described invention (Invention 7) may further include an operation processing unit that includes the first operation processing unit, the second operation processing unit and the third operation processing unit, and the sealing unit seals the first magnetic detection element unit, the second magnetic detection element unit, the third magnetic detection unit and the operation processing unit as a single body (Invention 9).

### EFFICACY OF THE INVENTION

The present invention, it is possible to provide a highly reliable magnetic sensor apparatus that includes a plurality of magnetic detection element units and plurality of operation processing units and that, even when abnormal situations arise in which erroneous physical quantities are calculated in the operation processing units, can swiftly comprehend those abnormalities.

### BRIEF DESCRIPTION OF THE DRAWINGS

FIG. 1 is a plan view schematically showing a configuration of a magnetic sensor apparatus according to the embodiment of the present invention.

FIG. 2 is a cross-sectional view along line A-A in FIG. 1, schematically showing a configuration of magnetic sensor apparatus according to the embodiment of the present invention.

FIG. 3 is a perspective view schematically showing a configuration of a magnetic sensor apparatus according to the embodiment of the present invention.

FIG. 4 is a block diagram schematically showing a configuration of a first magnetic sensor unit according to the embodiment of the present invention.

FIG. 5 is a block diagram schematically showing a configuration of a second magnetic sensor unit according to the embodiment of the present invention.

FIG. 6 is a block diagram schematically showing a configuration of a third magnetic sensor unit according to the embodiment of the present invention.

FIG. 7 is a graph showing the relationship between an external magnetic field and resistance values as differences in properties between a TMR element possessed by the first magnetic sensor unit and a TMR element possessed by the third magnetic sensor unit according to the embodiment of the present invention.

FIG. 8 is a perspective view schematically showing a configuration of the TMR element according to the embodiment of the present invention.

FIG. 9 is a cross-sectional view schematically showing a configuration of the TMR element according to the embodiment of the present invention.

FIG. 10 is a circuit diagram schematically showing a circuit configuration of the first magnetic detection element of the first magnetic sensor unit according to the embodiment of the present invention.

FIG. 11 is a circuit diagram schematically showing a circuit configuration of the second magnetic detection element of the first magnetic sensor unit according to the embodiment of the present invention.

FIG. 12 is a circuit diagram schematically showing a circuit configurationof the first magnetic detection element of the second magnetic sensor unit according to the embodiment of the present invention.

FIG. 13 is a circuit diagram schematically showing a circuit configuration of the second magnetic detection element of the second magnetic sensor unit according to the embodiment of the present invention.

FIG. 14 is a circuit diagram schematically showing a circuit configuration of the first magnetic detection element of the third magnetic sensor unit according to the embodiment of the present invention.

FIG. 15 is a circuit diagram schematically showing a circuit configuration of the second magnetic detection element of the third magnetic sensor unit according to the embodiment of the present invention.

FIG. 16 is a perspective view schematically showing a configuration of a position detection apparatus according to the embodiment of the present invention.

### DETAILED DESCRIPTION OF THE INVENTION

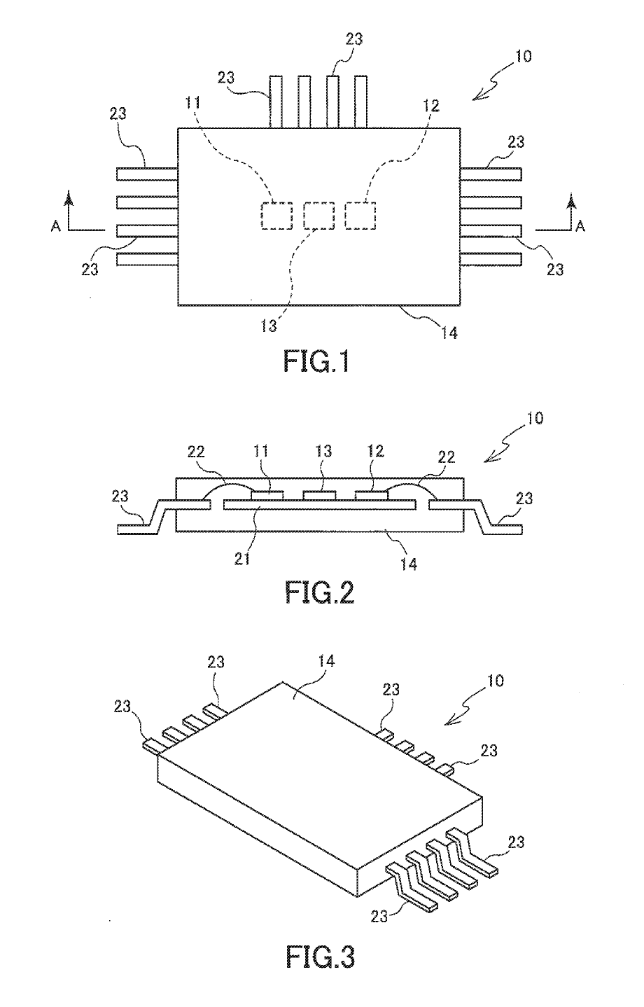

An embodiment of the present invention will be described with reference to the drawings. FIG. 1 is a plan view showing a schematic configuration of a magnetic sensor apparatus according to this embodiment, FIG. 2 is a cross-sectional view along line A-A in FIG. 1, showing a schematic configuration of the magnetic sensor apparatus according to this embodiment, and FIG. 3 is a perspective view showing a schematic configuration n of the magnetic sensor apparatus according to this embodiment.

As shown in FIGS. 1-3, a magnetic sensor apparatus 10 according to this embodiment includes a first magnetic sensor unit 11, a second magnetic sensor unit 12, a third magnetic sensor unit 13, and a sealing unit 14, which seals the first magnetic sensor unit 11, the second magnetic sensor unit 12 and the third magnetic sensor unit 13 as a single body.

The first magnetic sensor unit 11, the second magnetic sensor unit 12 and the third magnetic sensor unit 13 are provided on a base 21 and each is electrically connected to a connection lead 23 through a wiring unit 22 such as bonding wire or the like. The sealing unit 14 is composed of resin material (for example, epoxy resin or the like) that seals the first magnetic sensor unit 11, the second magnetic sensor unit 12 and the third magnetic sensor unit 13 as a single body.

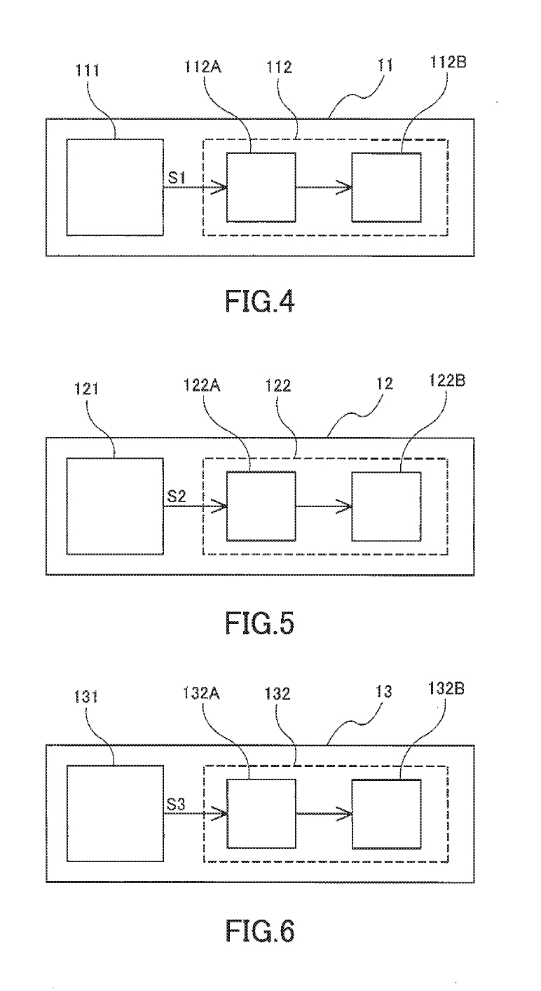

The first magnetic sensor unit 11 has a first magnetic detection element unit 111, which outputs a first sensor signal S1 based on changes in an external magnetic field, and a first operation processing unit 112, which calculates a physical quantity based on the first sensor signal S1 (see FIG. 4). The second magnetic sensor unit 12 has a second magnetic detection element unit 121, which outputs a second sensor signal S2 based on changes in the external magnetic field, and a second operation processing unit 122, which calculates a physical quantity based on the second sensor signal S2 (see FIG. 5). The third magnetic sensor unit 13 has a third magnetic detection element unit 131, which outputs a third sensor signal S3 based on changes in the external magnetic field, and a third operation processing unit 132, which calculates a physical quantity based on the third sensor signal S3 (see FIG. 6).

The first magnetic detection element unit 111, the second magnetic detection element unit 121 and the third magnetic detection element unit 131 all have magnetic detection elements. Examples of the magnetic detection elements include Hall elements, AMR elements, GMR elements, TMR elements and the like.

In this embodiment, the first magnetic sensor unit 11 and the third magnetic sensor unit 13 are the same type of magnetic sensor unit, but the second magnetic sensor unit 12 is a different type of magnetic sensor unit from the first magnetic sensor unit 11 and the third magnetic sensor unit 13. Specifically, as described below, the first operation processing unit 112, the second operation processing unit 122 and the third operation processing unit 132 calculate the physical quantity based on mutually differing types of operation algorithms.

In this embodiment, a configuration in which the magnetic detection elements possessed by the first magnetic detection element unit 111, the second magnetic detection element unit 121 and the third magnetic detection element unit 131 are all the same type of TMR element, but this is intended to be illustrative and not limiting. It is acceptable for the magnetic detection elements possessed by the first magnetic detection element unit 111 and the third magnetic detection element unit 131 to be a different type from the magnetic detection elements possessed by the second magnetic detection element unit 121.

For example, the magnetic detection elements possessed by the first magnetic detection element unit 111 and the third magnetic detection element unit 131 may be TMR elements, and the magnetic detection elements possessed by the second magnetic detection element unit 121 may be GMR elements.

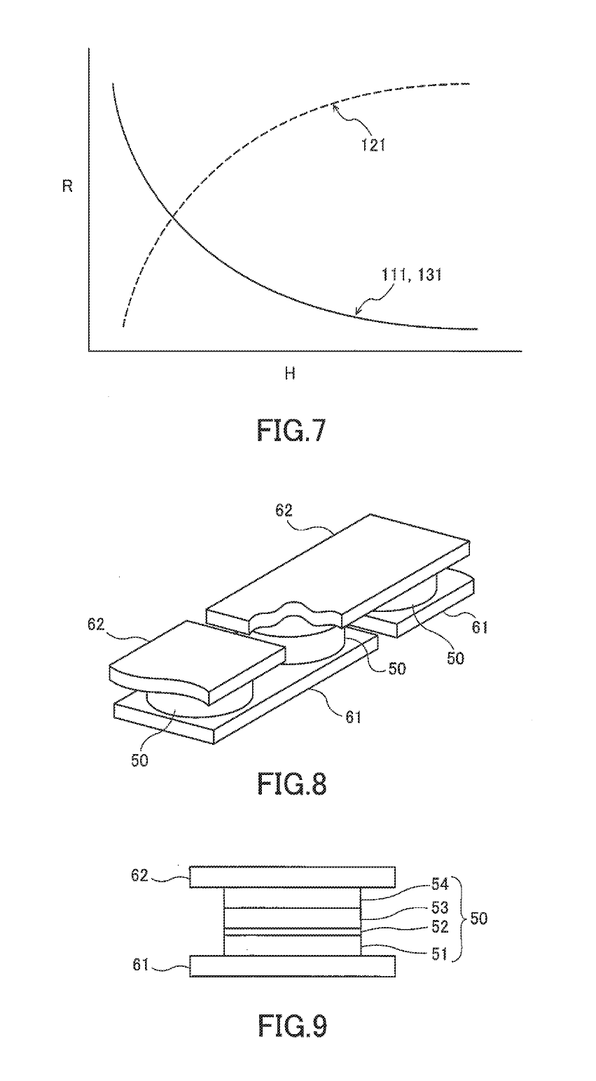

In addition, the magnetic detection elements possessed by the first magnetic detection element unit 111, the second magnetic detection element unit 121 and the third magnetic detection element unit 131 may all be TMR elements, but it would be acceptable for the TMR elements possessed by the first magnetic detection element unit 111 and the third magnetic detection element unit 131 to have different properties from the TMR elements possessed by the second magnetic detection element unit 121. For example, it would be acceptable to use, as the magnetic detection elements of the first through third magnetic detection element units 111˜131, TMR elements in which the behavior (for example, magnetic field sensitivity) of the change in resistance value in accordance with changes in the external magnetic field mutually differs. For example the TMR elements possessed by the first magnetic detection element unit 111 and the third magnetic detection element unit 131 can have the property that the resistance value R decreases in accordance with an increase in the external magnetic field H, but the TMR elements possessed by the second magnetic detection element 121 can have the property that the resistance value R increases in accordance with an increase in the external magnetic field H, as shown in FIG. 7.

The TMR elements possessed by first magnetic detection element unit 111, the second magnetic detection element unit 121 and the third magnetic detection element unit 131 have a plurality of bottom lead electrodes 61, a plurality of TMR laminated bodies 50 and a plurality of top lead electrodes 62, as shown in FIG. 8. The bottom lead electrodes 61 and the top lead electrodes 62 are composed of one type of conductive material out of Cu, Al, Au, Ta, Ti or the like, for example, or a compound film of two or more of the conductive materials, and the thicknesses thereof are respectively 0.3˜2.0 μm.

The plurality of bottom lead electrodes 61 is provided on a substrate (not shown). Each of the plurality of bottom lead electrodes 61 has a long, slender, roughly rectangular shape and is provided to have a predetermined gap between two adjacent bottom lead electrodes 61 in the electrical series direction of the plurality of TMR laminated bodies 50 arranged in an array. Near both ends of the bottom lead electrodes 61 in the lengthwise direction, the TMR laminated bodies 50 are provided. That is, two TMR laminated bodies 50 are provided on each of the bottom lead electrodes 61.

The TMR laminated bodies 50 according to this embodiment have a magnetization pinned layer 53, in which the magnetization direction is fixed, a free layer 51, in which the magnetization direction changes in accordance with the direction of an applying magnetic field, a non-magnetic layer 52, which is positioned between the magnetization pinned layer 53 and the free layer 51, and an antiferromagnetic layer 54, as shown in FIG. 9.

The TMR laminated bodies 50 have a structure in which the free layer 51, the non-magnetic layer 52, the magnetization pinned layer 53 and the antiferromagnetic layer 54 are laminated in that order from the bottom lead electrode 61 side. The free layer 51 is electrically connected to the bottom lead electrode 61, and the antiferromagnetic layer 54 is electrically connected to the top lead electrode 62. Examples of materials composing the free layer 51 and the magnetization pinned layer 53 include, for example, NiFe, CoFe, CoFeB, CoFeNi, Co₂MnSi, Co₂MnGe, FeOx (oxides of Fe), or the like. The thicknesses of the free layer 51 and the magnetization pinned layer 53 are around 1˜10 nm each.

The non-magnetic layer 52 is a tunnel barrier layer, and is a film vital for causing the tunnel magnetoresistance effect (TMR effect) to be realized in the TMR laminated body 50. The materials composing the non-magnetic layer 52, Cu, Au, Ag, Zn, Ga, TiOx, ZnO, InO, SnO, GaN, ITO (Indium Tin Oxide), Al₂O₃, MgO or the like can be given as examples. The non-magnetic layer 52 may be composed of a laminated film with two or more layers. For example, the non-magnetic layer 52 can be composed of a three-layer laminated film of Cu/ZnO/Cu, or a three-layer laminated film of Cu/ZnO/Zn, with one of the Cu replaced with a Zn. The thickness of the non-magnetic layer 52 is around 0.1˜5 nm.

The antiferromagnetic layer 54 is composed of antiferromagnetic materials containing Mn and at least one type of element selected from a group including Pt, Ru, Rh, Pd, Ni, Cu, Ir, Cr and Fe, for example. The Mn content in this antiferromagnetic material is for example around 35˜95 atom %. The antiferromagnetic layer 54 composed of the antiferromagnetic material is exchange-coupled with the magnetization pinned layer 53 and serves to fix the direction of magnetization of the magnetization pinned layer 53.

The plurality of top lead electrodes 62 is provided on the plurality of TMR laminated bodies 50. Each of the top lead electrodes 62 has a long, slender, roughly rectangular shape. The top lead electrodes 62 are provided to have a predetermined gap between two adjacent top lead electrodes 62 in the electrical series direction of the plurality of TMR laminated bodies 50 arranged in an array and so that the plurality of TMR laminated bodies 50 is connected in series, and the antiferromagnetic layers 54 of two adjacent TMR laminated bodies 50 are electrically connected to each other. The TMR laminated bodies 50 may have a composition in which the antiferromagnetic layer 54, the magnetization pinned layer 53, the non-magnetic layer 52 and the free layer 51 are laminated in that order from the bottom lead electrode 61. In addition, a cap layer (protective layer) may be provided between the free layer 51 and the bottom lead electrode 61 or the top lead electrode 62.

In the TMR laminated bodies 50, the resistance value changes in accordance with the angle formed between the direction of magnetization of the free layer 51 and the direction of magnetization of the magnetization pinned layer 53. The resistance value is minimized when this angle is 0° (when the magnetization directions are mutually parallel), and the resistance value is maximized when this angle is 180° (when the magnetization directions are mutually antiparallel).

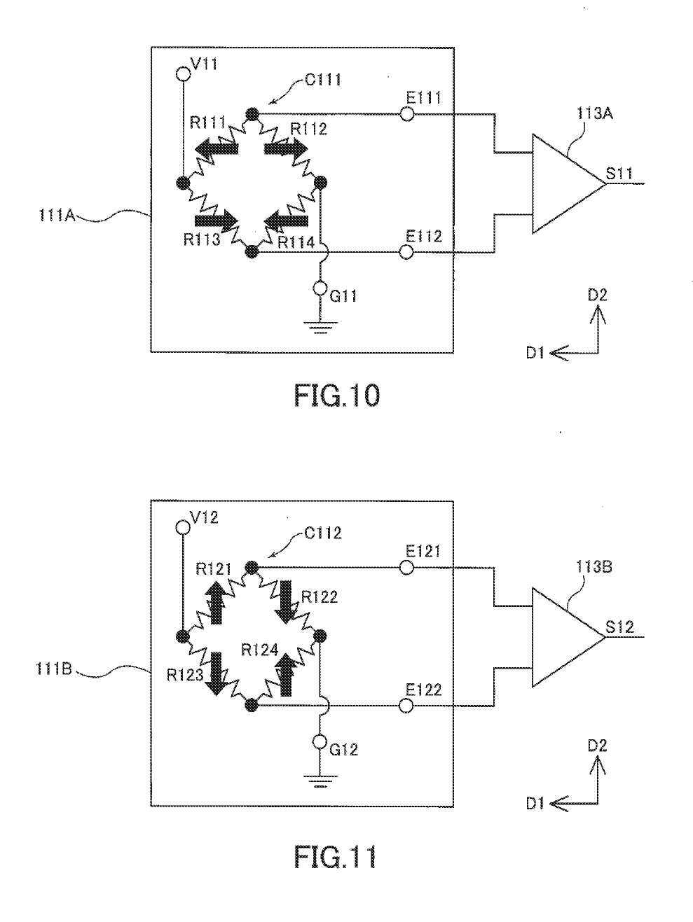

As shown in FIG. 10 and FIG. 11, the first magnetic detection element unit 111 has a first magnetic detection element 111A and a second magnetic detection element 111B that output a first signal S1 (the first signal S11 and the second signal S12) based on changes in the external magnetic field, and the first operation processing unit 112 calculates the physical quantity based on the first sensor signal S1 (the first signal S11 and the second signal S12) output from the first magnetic detection element 111A and the second magnetic detection element 111B.

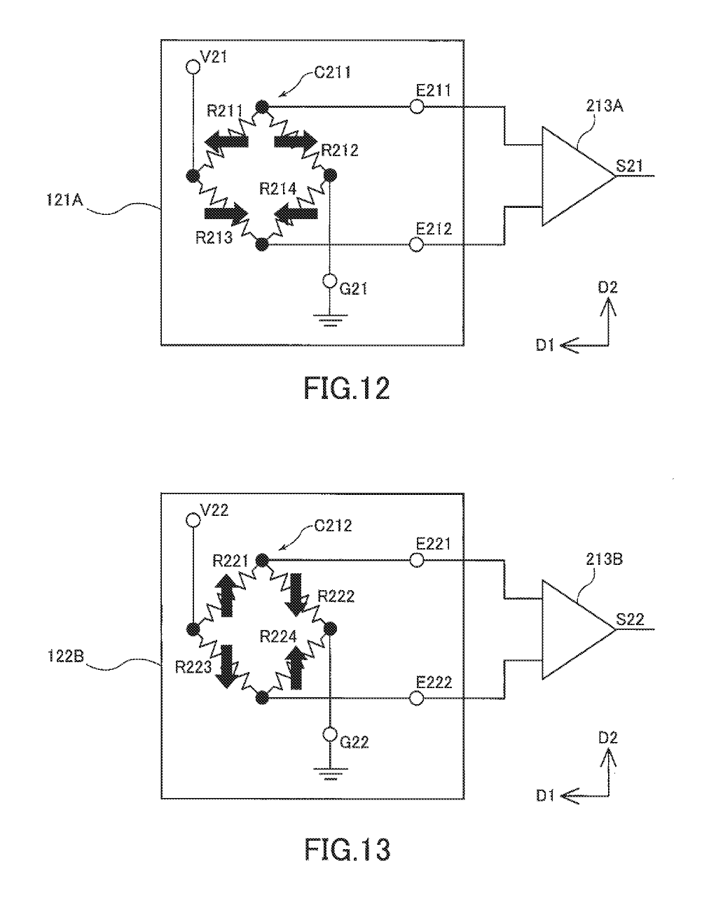

As shown in FIG. 12 and FIG. 13, the second magnetic detection element unit 121 has a first magnetic detection element 121A and a second magnetic detection element 121B that output a second sensor signal S2 (the first signal S21 and the second signal S22) based on changes in the external magnetic field, and the second operation processing unit 122 calculates the physical quantity based on the second sensor signal S2 (the first signal S21 and the second signal S22) output from the first magnetic detection element 121A and the second magnetic detection element 121B.

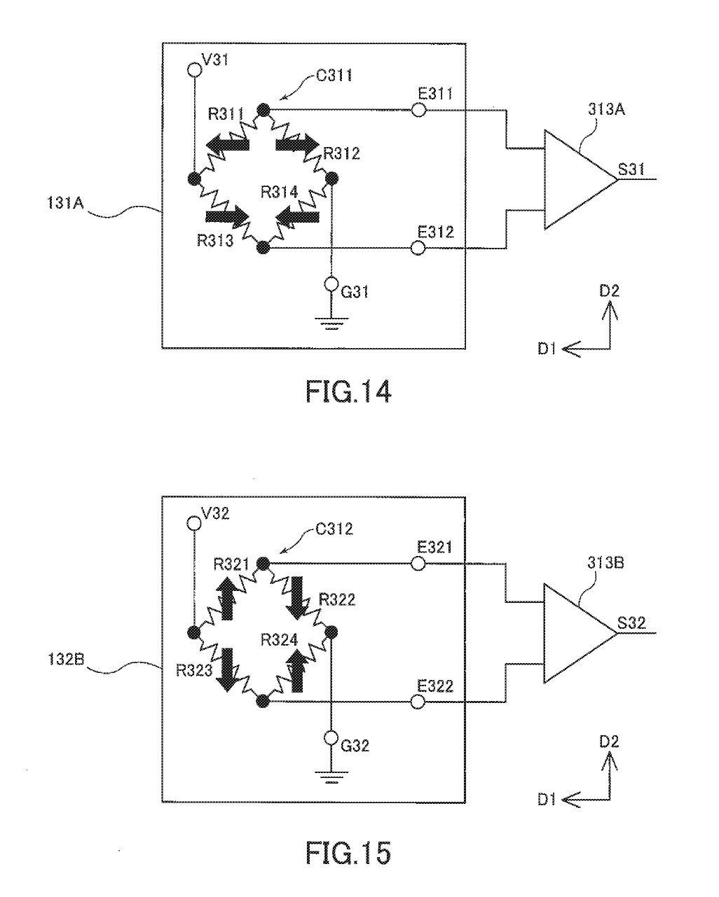

As shown in FIG. 14 and FIG. 15, the third magnetic detection element unit 131 has a first magnetic detection element 131A and a second magnetic detection element 131B that output a third sensor signal S3 (the first signal S31 and the second signal S32) based on changes in the external magnetic field, and the third operation processing unit 132 calculates the physical quantity based on the third sensor signal S3 (the first signal S31 and the second signal S32) output from the first magnetic detection element 131A and the second magnetic detection element 131B.

The first operation processing unit 112, the second operation processing unit 122 and the third operation processing unit 132 include A/D (analog-digital) conversion units 112A, 122A and 132A that convert analog signals (the first signals S11, S21 and S31, and the second signals S12, S22 and S32) output from the first magnetic detection elements 111A, 121A and 131A and the second magnetic detection elements 111B, 121B and 131B, into digital signals, and operation units 1126, 1226 and 1326 that perform operation processing on the digital signals converted to digital by the A/D conversion units 112A, 122A and 132A and calculate the physical quantity.

The first magnetic detection elements 111A, 121A and 131A, and the second magnetic detection elements 111B, 121B and 131B each include at least one TMR element and may include a pair of TMR elements connected in series. In this case, each of the first magnetic detection elements 111A, 121A and 131A and the second magnetic detection elements 111B, 121B and 131B has a Wheatstone bridge circuit including the pair of TMR elements connected in series.

As shown in FIG. 10, a Wheatstone bridge circuit C111 of the first magnetic detection element 111A includes a power source port V11, a ground port G11, two output ports E111 and E112, a first pair of TMR elements R111 and R112 connected in series and a second pair of TMR elements R113 and R114 connected in series. One end of each of the TMR elements R111 and R113 is connected to the power source port V11. The other end of the TMR element R111 is connected to one end of the TMR element R112 and the output port E111. The other end of the TMR element R113 is connected to one end of the TMR element R114 and the output port E112. The other end of each of the TMR elements R112 and R114 is connected to the ground port G11. A predetermined power supply voltage is applied to the power source port V11, and the ground port G11 is connected to ground.

As shown in FIG. 11, a Wheatstone bridge circuit C112 of the second magnetic detection element 111B has the same composition as the Wheatstone bridge circuit C111 of the first magnetic detection element 111A. The Wheatstone bridge circuit C112 includes a power source port V12, a ground port G12, two output ports E121 and E122, a first pair of TMR elements R121 and R122 connected in series, and a second pair of TMR elements R123 and R124 connected in series. One end of each of the TMR elements R121 and R123 is connected to the power source port V12. The other end of the TMR element R121 is connected to one end of the TMR element R122 and the output port E121. The other end of the TMR element R123 is connected to one end of the TMR element R124 and the output port E122. The other end of each of the TMR elements R122 and R124 is connected to the ground port G12. A predetermined power supply voltage is applied to the power source port V12, and the ground port G12 is connected to ground.

As shown in FIG. 12, a Wheatstone bridge circuit C121 of the first magnetic detection element 121A includes a power source port V21, a ground port G21, two output ports E211 and E212, a first pair of TMR elements R211 and R212 connected in series and a second pair of TMR elements R213 and R214 connected in series. One end of each of the TMR elements R211 and R213 is connected to the power source port V21. The other end of the TMR element R211 is connected to one end of the TMR element R212 and the output port E211. The other end of the TMR element R213 is connected to one end of the TMR element R214 and the output port E212. The other end of each of the TMR elements R212 and R214 is connected to the ground port G21. A predetermined power supply voltage is applied to the power source port V21, and the ground port G21 is connected to ground.

As shown in FIG. 13, a Wheatstone bridge circuit C122 of the second magnetic detection element 121B has the same composition as the Wheatstone bridge circuit C121 of the first magnetic detection element 121A. The Wheatstone bridge circuit C122 includes a power source port V22, a ground port G22, two output ports E221 and E222, a first pair of TMR elements R221 and R222 connected in series and a second pair of TMR elements R223 and R224 connected in series. One end of each of the TMR elements R221 and R223 is connected to the power source port V22. The other end of the TMR element R221 is connected to one end of the TMR element R222 and the output port E221. The other end of the TMR element R223 is connected to one end of the TMR element R224 and the output port E222. The other end of each of the TMR elements R222 and R224 is connected to the ground port G22. A predetermined power supply voltage is applied to the power source port V22, and the ground port G22 is connected to ground.

As shown in FIG. 14, a Wheatstone bridge circuit C131 of the first magnetic detection element 131A includes a power source port V31, a ground port G31, two output ports E311 and E312, a first pair of TMR elements R311 and R312 connected in series and a second pair of TMR elements R313 and R314 connected in series. One end of each of the TMR elements R311 and R313 is connected to the power source port V31. The other end of the TMR element R311 is connected to one end of the TMR element R312 and the output port E311. The other end of the TMR element R313 is connected to one end of the TMR element R314 and the output port E312. The other end of each of the TMR elements R312 and R314 is connected to the ground port G31. A predetermined power supply voltage is applied to the power source port V31, and the ground port G31 is connected to ground.

As shown in FIG. 15, a Wheatstone bridge circuit C132 of the second magnetic detection element 131B has the same composition as the Wheatstone bridge circuit C131 of the first magnetic detection element 131A. The Wheatstone bridge circuit C132 includes a power source port V32, a ground port G32, two output ports E321 and E322, a first pair of TMR elements R321 and R322 connected in series and a second pair of TMR elements R323 and R324 connected in series. One end of each of the TMR elements R321 and R323 is connected to the power source port V32. The other end of the TMR element R321 is connected to one end of the TMR element R322 and the output port E321. The other end of the TMR element R323 is connected to one end of the TMR element R324 and the output port E322. The other end of each of the TMR elements R322 and R324 is connected to the ground port G32. A predetermined power supply voltage is applied to the power source port V32, and the ground port G32 is connected to ground.

In this embodiment, the above-described TMR element (see FIGS. 8, 9) is used as each of the TMR elements R111˜R114, R121˜R124, R211˜R214, R221˜R224, R311˜R314 and R321˜R324 included in the Wheatstone bridge circuits C111, C112, C121, C122, C131 and C132.

In FIG. 10 to FIG. 15, the magnetization directions of the magnetization pinned layers 53 of the TMR elements R111˜R114, R121˜R124, R211˜R214, R221˜R224, R311˜R314 and R321˜R324 are indicated by the filled-in arrows. In the first magnetic detection elements 111A, 121A and 131A, the magnetization directions of the magnetization pinned layers 53 of the TMR elements R111˜R114, R211˜R214 and R311˜R314 are parallel to a first direction D1. The magnetization direction of the magnetization pinned layers 53 of the TMR elements R111 and R114 is antiparallel to the magnetization direction of the magnetization pinned layers 53 of the TMR elements R112 and R113. In addition, the magnetization direction of the magnetization pinned layers 53 of the TMR elements R211 and R214 is antiparallel to the magnetization direction of the magnetization pinned layers 53 of the TMR elements R212 and R213. Furthermore, the magnetization direction of the magnetization pinned layers 53 of the TMR elements R311 and R314 is antiparallel to the magnetization direction of the magnetization pinned layers 53 of the TMR elements R312 and R313.

In the second magnetic detection elements 111B, 121B and 131B, the magnetization directions of the magnetization pinned layers 53 of the TMR elements R121˜R124, R221˜R224 and R321˜R324 are orthogonal to a first direction and parallel to a second direction. The magnetization direction of the magnetization pinned layers 53 of the TMR elements R121 and R124 is antiparallel to the magnetization direction of the magnetization pinned layers 53 of the TMR elements R122 and R123. In addition, the magnetization direction of the magnetization pinned layers 53 of the TMR elements R221 and R224 is antiparallel to the magnetization direction of the magnetization pinned layers 53 of the TMR elements R222 and R223. Furthermore, the magnetization direction of the magnetization pinned layers 53 of the TMR elements R321 and R324 is antiparallel to the magnetization direction of the magnetization pinned layers 53 of the TMR elements R322 and R323.

In the first magnetic detection element 111A and the second magnetic detection element 111B of the first magnetic detection element unit 111, the electric potential difference between the output ports E111 and E112 and the output ports E121 and E122 changes in accordance with the external magnetic field, and the first signal S11 and the second signal S12 are output to the first operation processing unit 112 as signals indicating magnetic field strength. In addition, in the first magnetic detection element 121A and the second magnetic detection element 121B of the second magnetic detection element unit 121, the electric potential difference between the output ports E211 and E212 and the output ports E221 and E222 changes in accordance with the external magnetic field, and the first signal S21 and the second signal S22 are output to the second operation processing unit 122 as signals indicating magnetic field strength. Furthermore, in the first magnetic detection element 131A and the second magnetic detection element 131B of the third magnetic detection element unit 131, the electric potential difference between the output ports E311 and E312 and the output ports E321 and E322 changes in accordance with the external magnetic field, and the first signal S31 and the second signal S32 are output to the third operation processing unit 132 as signals indicating magnetic field strength.

A first difference detector 113A outputs a signal corresponding to the electric potential difference of the output ports E111 and E112 to the A/D conversion unit 112A as the first signal S11. A second difference detector 113B outputs a signal corresponding to the electric potential difference of the output ports E121 and E122 to the A/D conversion unit 112A as the second signal S12.

In addition, a first difference detector 213A outputs a signal corresponding to the electric potential difference of the output ports E211 and E212 to the A/D conversion unit 122A as the first signal S21. A second difference detector 213B outputs a signal corresponding to the electric potential difference of the output ports E221 and E222 to the A/D conversion unit 122A as the second signal S22.

Furthermore, a first difference detector 313A outputs a signal corresponding to the electric potential difference of the output ports E311 and E312 to the A/D conversion unit 132A as the first signal S31. A second difference detector 313B outputs a signal corresponding to the electric potential difference of the output ports E321 and E322 to the A/D conversion unit 132A as the second signal S32.

As shown in FIG. 10 and FIG. 11, in the first magnetic detection element unit 111, the magnetization direction of the magnetization pinned layers 53 of the TMR elements R111˜R114 in the first magnetic detection element 111A and the magnetization direction of the magnetization pinned layers 53 of the TMR elements R121˜R124 in the second magnetic detection element 111B are orthogonal to each other. In this case, the waveform of the first signal S11 becomes a cosine waveform dependent on the physical quantity, and the waveform of the second signal S12 becomes a sine waveform dependent on the physical quantity. In this embodiment, the phase of the second signal S12 differs by ¼ of a signal cycle from the phase of the first signal S11.

As shown in FIG. 12 and FIG. 13, in the second magnetic detection element unit 121, the magnetization direction of the magnetization pinned layers 53 of the TMR elements R211˜R214 in the first magnetic detection element 121A and the magnetization direction of the magnetization pinned layers 53 of the TMR elements R221˜R224 in the second magnetic detection element 121B are orthogonal to each other. In this case, the waveform of the first signal S21 becomes a cosine waveform dependent on the physical quantity, and the waveform of the second signal S22 becomes a sine waveform dependent on the physical quantity. In this embodiment, the phase of the second signal S22 differs by ¼ of a signal cycle from the phase of the first signal S21.

Furthermore, as shown in FIG. 14 and FIG. 15, in the third magnetic detection element unit 131, the magnetization direction of the magnetization pinned layers 53 of the TMR elements R311˜R314 in the first magnetic detection element 131A and the magnetization direction of the magnetization pinned layers 53 of the TMR elements R321˜R324 in the second magnetic detection element 131B are orthogonal to each other. In this case, the waveform of the first signal S31 becomes a cosine waveform dependent on the physical quantity, and the waveform of the second signal S32 becomes a sine waveform dependent on the physical quantity. In this embodiment, the phase of the second signal S32 differs by ¼ of a signal cycle from the phase of the first signal S31.

The A/D conversion units 112A, 122A and 132A convert the first signals S11, S21 and S31 and the second signals S12, S22 and S32 output from the first magnetic detection elements 111A, 121A and 131A and the second magnetic detection elements 111B, 121B and 131B (analog signals relating to the physical quantity) into digital signals, and these digital signals are input into the operation units 112B, 122B and 132B.

The operation units 112B, 122B and 132B perform operation processing on the digital signals converted from analog signals by the A/D conversion units 112A, 122A and 132A and calculate the physical quantity. These operation units 112B, 122B and 132B include microcomputers or the like, for example.

In this embodiment, the operation unit 112B of the first operation processing unit 112, the operation unit 122B of the second operation processing unit 122 and the operation unit 132B of the third operation processing unit 132 calculate the physical quantity based on a plurality of mutually differing operation algorithms. Through this, for example, when the operation unit 112B calculates an erroneous physical quantity due to factors unique to the program of the operation unit 112B of the first operation processing unit 112, the other two operation units 122B and 132B calculate physical quantities that substantially match each other, but there are cases in which the physical quantity calculated by the operation unit 112B deviates greatly from the physical quantity calculated by the operation units 122B and 132B. In such a case, it is possible to determine that an abnormal physical quantity was output due to factors unique to the operation algorithm in the program of the operation unit 112B of the first operation process unit 112, so it is possible to swiftly comprehend the occurrence of an abnormal situation in the magnetic sensor apparatus 1.

As operation algorithms for the operation units 112B, 1228 and 132B to calculate the physical quantity, for example the following algorithms are examples: an arctangent algorithm that calculates the arctangent (a tan) using the digital signals converted from analog signals by the A/D conversion units 112A, 122A and 132A and calculates the physical quantity from the calculation results thereof; a look-up table algorithm that has a look-up table indicating the correlation between the above-described digital signals and the physical quantity, stored in nonvolatile memory (not shown), and look-up table algorithm extracts the physical quantity by referencing the look-up table based on the digital signals; and a tracking group algorithm that calculates the physical quantity by performing feedback control so that the deviation between the physical quantity such as the rotation angle of the moving body and the physical quantities calculated by the first through third operation processing units 112˜132 converge to a predetermined value (usually 0).

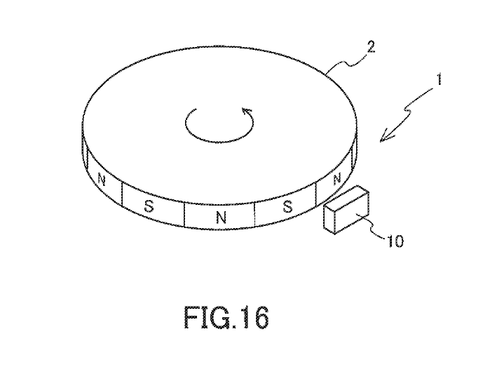

Next, a position detection apparatus using the magnetic sensor apparatus 10 according to this embodiment will be described. FIG. 16 is a perspective view showing a schematic configuration of a position detection apparatus according to this embodiment.

As shown in FIG. 16, the position detection apparatus 1 according to this embodiment includes a magnetic sensor apparatus 10 and a moving body 2 capable of moving relative to the magnetic sensor apparatus 10. In this embodiment, the description takes as an example a rotary encoder provided with a rotational moving body 2 that rotationally moves about a predetermined axis of rotation, as the position detection apparatus 1, but this is intended to be illustrative and not limiting, for it would be acceptable to have a linear encoder or the like provided with a moving body 2 that moves linearly in a predetermined direction relative to the magnetic sensor apparatus 10. In the situation shown in FIG. 16, the rotational moving body 2 is a rotary magnet in which N poles and S poles are alternatingly magnetized about the outer circumference.

The operation units 112B, 122B and 132B in the magnetic sensor apparatus 10 perform operation processing on the digital signals converted from analog signals by the A/D conversion units 112A, 122A and 132A and calculate rotation angles θ1, θ2 and θ3 of the rotational moving body 2 as the physical quantities

For example, the operation unit 112B of the first operation processing unit 112 can calculate the rotation angle θ1 of the rotational moving body 2 through the arctangent computation shown in the following equation.

θ1=a tan(S11/S12)

Within a 360° range, there are 2 solutions of the rotation angle θ1 in the above equation, differing by 180°. However, through the combination of signs of the first signal S11 and the second signal S12, it is possible to determine which of the two solutions to the above equation is the true value of the rotation angle θ1. That is, when the first signal S11 has a positive value, the rotation angle θ1 is larger than 0° and smaller than 180°. When the first signal S11 has a negative value, the rotation angle θ1 is larger than 180° and smaller than 360°. When the second signal S12 has a positive value, the rotation angle θ1 is within the range of at least 0° or more and less than 90° and larger than 270° and smaller than 360°. When the second signal S12 has a negative value, the rotation angle θ1 is larger than 90° and smaller than 270°. The operation unit 112B calculates the rotation angle θ1 within the 360° range based on the determination of the combination of positive and negative signs of the first signal S11 and second signal S12.

The operation unit 122B of the second operation processing unit 122 can, for example, calculate the rotation angle θ2 of the rotational moving body 2 by referencing a look-up table stored in unillustrated memory and extracting the value corresponding to the digital signals converted from analog signals by the A/D conversion unit 122A.

The operation unit 132B of the third operation processing unit 132 can, for example, calculate the rotation angle θ3 of the rotational moving body 2 by finding the deviation between the true rotation angle θ of the rotational moving body 2 (the actual rotation angle of the rotational moving body 2) and the calculated rotation angle φ calculated based on the digital signals converted from analog signals by the A/D conversion unit 132A and performing feedback control so that this deviation usually converges to zero.

In the position detection apparatus 1 according this embodiment having the above-described configuration, when the external magnetic field changes accompanying rotational movement of the rotational moving body 2, the resistance values of the TMR elements R111˜R114 and R121˜R124 of the first magnetic detection element unit 111 change in accordance with the change in that external magnetic field, and the first signal S11 and the second signal S12 are output from the first and second difference detectors 113A and 1138 in accordance with the electric potential difference between the output ports E111, E112, E121 and E122 of the first magnetic detection element unit 111. Then, the first signal S11 and the second signal S12 output from the first and second difference detectors 113A and 1138 are converted into digital signals by the A/D conversion unit 112A. Following this, the rotation angle θ1 of the rotational moving body 2 is calculated by the operation unit 112B.

In addition, similarly, in the second magnetic detection element unit 121, the resistance values of the TMR elements R211˜R214 and R221˜R224 change and the first signal S21 and the second signal S22 are output from the first and second difference detectors 213A and 2138 in accordance with the electric potential difference between the output ports E211, E212, E221 and E222 of the second magnetic detection element unit 121. Then, the first signal S21 and the second signal S22 output from the first and second difference detectors 213A and 2138 are converted into digital signals by the A/D conversion unit 122A. Following this, the rotation angle θ2 of the rotational moving body 2 is calculated by the operation unit 122B.

Furthermore, similarly in the third magnetic detection element unit 131, the resistance values of the TMR elements R311˜R314 and R321˜R324 change and the first signal S31 and the second signal S32 are output from the first and second difference detectors 313A and 3138 in accordance with the electric potential difference between the output ports E311, E312, E321 and E322 of the third magnetic detection element unit 131. Then, the first signal S31 and the second signal S32 output from the first and second difference detectors 313A and 3138 are converted into digital signals by the A/D conversion unit 132A. Following this, the rotation angle θ3 of the rotational moving body 2 is calculated by the operation unit 132B.

The rotation angles θ1˜θ3 respectively calculated by the first through third magnetic sensor units 11˜13 are output to an electronic control unit (ECU) of the application (for example, an electric power steering apparatus or the like) in which the position detection apparatus of this embodiment is installed. In the electronic control unit, the movement of this application is controlled based on the above-described rotation angles θ1˜θ3.

In the magnetic sensor apparatus 10 according to this embodiment, when obstacles arise due to factors (common factors) unique to the program of the first operation processing unit 112 (operation unit 112B) of the first magnetic sensor unit 11, an abnormality is recognized in the value of the rotation angle θ1 output from the first magnetic sensor unit 11. For example, in the operation unit 112B of the first operation processing unit 112, the rotation angle θ1 is computed through an arctangent calculation, but because there are discontinuities at ±90° in the arctangent function, abnormal situations can arise, such as computing a rotation angle that has rapidly changed so that it is impossible to obtain the rotation angle continuously.

However, the second magnetic sensor unit 12 and the third magnetic sensor unit 13 compute and output the physical quantity through different types of operation algorithms (the second operation algorithm and the third operation algorithm) from the operation algorithm (first operation algorithm) in the first operation processing unit 112 of the first magnetic sensor unit 11, so the obstacles caused by the above-described common factors do not arise.

Consequently, the above-described abnormality is not recognized in the output values from the second magnetic sensor unit 12 and the third magnetic sensor unit 13. Hence, because the value of the rotation angle θ1 output from the first magnetic sensor unit 11 deviates greatly from the rotation angles θ2 and θ3 output from the second magnetic sensor unit 12 and the third magnetic sensor unit 13, it is possible to swiftly comprehend the abnormality.

In addition, by specifying that the obstacle was produced in the first magnetic sensor unit 11, control based on the values of the rotation angles θ2 and θ3 output from the second magnetic sensor unit 12 and the third magnetic sensor unit 13 becomes possible, and it is possible to ensure redundancy in the magnetic sensor apparatus 10. Accordingly, with this embodiment, even when obstacles caused by factors unique to the programs of the first through third operation processing units 112˜132 of the first through third magnetic sensor units 11˜13 arise, it is possible to prevent functional breakdown of the magnetic sensor apparatus 10 and to improve reliability.

Similarly, when obstacles arise caused by factors (common factors) unique to the program of the second operation processing unit 122 (operation unit 122B) of the second magnetic sensor unit 12, an abnormality is recognized in the value of the rotation angle θ2 output from the second magnetic sensor unit 12. In this case as well, the obstacle caused by the above-described common factors does not arise in the first magnetic sensor unit 11 and the third magnetic sensor unit 13, and the above-described abnormality is not recognized in the output values from the first magnetic sensor unit 11 and the third magnetic sensor unit 13. Hence, because the value of the rotation angle θ 2 output from the second magnetic sensor unit 12 deviates greatly from the rotation angles θ1 and θ3 output from the first magnetic sensor unit 11 and the third magnetic sensor unit 13, it is possible to swiftly comprehend the abnormality.

In addition, when obstacles arise caused by factors (common factors) unique to the program of the third operation processing unit 132 (operation unit 132B) of the third magnetic sensor unit 13, an abnormality is recognized in the value of the rotation angle θ3 output from the third magnetic sensor unit 13. Also in this case, the obstacles caused by the above-described common factors do not arise in the first magnetic sensor unit 11 and the second magnetic sensor unit 12, and the above-described abnormality is not recognized in the output values from the first magnetic sensor unit 11 and the second magnetic sensor unit 12. Hence, because the value of the rotation angle θ3 output from the third magnetic sensor unit 13 deviates greatly from the rotation angles θ1 and θ2 output from the first magnetic sensor unit 11 and the second magnetic sensor unit 12, it is possible to swiftly comprehend the abnormality.

The above-described embodiment was described to facilitate understanding of the present invention and is intended to be illustrative and not limiting. Accordingly, each element disclosed in the above-described embodiment should be construed to include all design changes and equivalents falling within the technical scope of the present invention.

In the above-described embodiment, an example was described having three magnetic sensor units consisting of the first magnetic sensor unit 11, the second magnetic sensor unit 12 and the third magnetic sensor unit 13, but this is intended to be illustrative and not limiting, for the magnetic sensor apparatus 10 may have at least two types of magnetic sensor units, for example.

In the above-described embodiment, the magnetic sensor apparatus 10 was described taking as an example a situation in which the apparatus includes the first magnetic sensor unit 11, which includes the first magnetic detection element unit 111 and the first operation processing unit 112, the second magnetic sensor unit 12, which includes the second magnetic detection element unit 121 and the second operation processing unit 122, and the third magnetic sensor unit 13, which includes the third magnetic detection element unit 131 and the third operation processing unit 132, but the present invention is not limited to such a configuration. For example, the magnetic sensor apparatus 10 may have the first magnetic detection element unit 111, the second magnetic detection element unit 121 and the third magnetic detection element unit 131, and a single operation processing unit that calculates the physical quantity based on the first sensor signal S1, the second sensor signal S2 and the third sensor signal S3 respectively output from each of these. In this case, the operation processing unit can calculate the first physical quantity (for example, the rotation angle θ1) through the first operation algorithm based on the first sensor signal S1, can calculate the second physical quantity (for example, the rotation angle θ2) through the second operation algorithm based on the second sensor signal S2, and can calculate the third physical quantity (for example, the rotation angle θ3) through the third operation algorithm based on the third sensor signal S3. Furthermore, the operation processing unit may be sealed integrally in the sealing unit 14 along with the first through third magnetic detection element units 111˜131, or may not be sealed in the sealing unit 14 and instead be a separate body from the first through third magnetic detection element units 111˜131.

1. A magnetic sensor apparatus comprising:
a first magnetic detection element unit that outputs a first sensor signal based on change in an external magnetic field;
a second magnetic detection element unit that outputs a second sensor signal based on change in the external magnetic field;
a first operation processing unit that calculates a predetermined physical quantity based on the first sensor signal;
a second operation processing unit that calculates a predetermined physical quantity based on the second sensor signal; and
a sealing unit that seals at least the first magnetic detection element unit and the second magnetic detection element unit as a single body;
wherein the first operation processing unit calculates the physical quantity based on a first operation algorithm; and
the second operation processing unit calculates the physical quantity, which is of the same type as the physical quantity calculated by the first operation processing unit, based on a second operation algorithm of a different type from the first operation algorithm.

2. The magnetic sensor apparatus according to claim 1, wherein the first magnetic detection element unit and the second magnetic detection element unit both include magnetoresistive effect elements.

3. The magnetic sensor apparatus according to claim 2, wherein the magnetoresistive effect elements included in the first magnetic detection element unit and the magnetoresistive effect elements included in the second magnetic detection element unit are the same type of magnetoresistive effect elements.

4. The magnetic sensor apparatus according to claim 3, wherein the magnetoresistive effect elements included in the first magnetic detection element unit and the magnetoresistive effect elements included in the second magnetic detection element unit are magnetoresistive effect elements with mutually differing behavior in resistance value changes based on changes in the external magnetic field.

5. The magnetic sensor apparatus according to claim 1, further comprising a first magnetic sensor unit; which includes the first magnetic detection element unit and the first operation processing unit, and a second magnetic sensor unit, which includes the second magnetic detection element unit and the second operation processing unit;
wherein the sealing unit seals the first magnetic sensor unit and the second magnetic sensor unit as a single body.

6. The magnetic sensor apparatus according to claim 1, further comprising an operation processing unit that includes the first operation processing unit and the second operation processing unit;
wherein the sealing unit seals the first magnetic detection element unit, the second magnetic detection element unit and the operation processing unit as a single body.

7. The magnetic sensor apparatus according to claim 1, further comprising a third magnetic detection element unit, which outputs a third sensor signal based on change in the external magnetic field, and a third operation processing unit, which calculates a predetermined physical quantity based on the third sensor signal;
wherein the sealing unit seals at least the first magnetic detection element unit; the second magnetic detection element unit and the third magnetic detection element unit as a single body; and
the third operation processing unit calculates the physical quantity, which is of the same type as the physical quantities respectively calculated by the first operation processing unit and the second operation processing unit, based on a third operation algorithm of a type differing from both the first operation algorithm and the second operation algorithm.

8. The magnetic sensor apparatus according to claim 7, further comprising a first magnetic sensor unit, which includes the first magnetic detection element unit and the first operation processing unit, a second magnetic sensor unit, which includes the second magnetic detection element unit and the second operation processing unit, and a third magnetic sensor unit, which includes the third magnetic detection element unit and the third operation processing unit;
wherein the sealing unit seals the first magnetic sensor unit, the second magnetic sensor unit and the third magnetic sensor unit as a single body.

9. The magnetic sensor apparatus according to claim 7, further comprising an operation processing unit that includes the first operation processing unit, the second operation processing unit and the third operation processing unit;
wherein the sealing unit seals the first magnetic detection element unit, the second magnetic detection element unit, the third magnetic detection element unit and the operation processing unit as a single body.
